(19) United States
(12) Patent Application Publication
(10) Pub. No.: US 2017/0372759 A1
(43) Pub. Date: Dec. 28, 2017

(54) ACTIVE CONTROL CIRCUIT, INTERNAL VOLTAGE GENERATION CIRCUIT, MEMORY APPARATUS AND SYSTEM USING THE SAME

(71) Applicant: SK hynix Inc., Icheon-si (KR)

(72) Inventor: Min Su KIM, Icheon-si Gyeonggi-do (KR)

(21) Appl. No.: 15/279,838

(22) Filed: Sep. 29, 2016

(30) Foreign Application Priority Data
Jun. 22, 2016 (KR) 10-2016-0078087

(51) Int. Cl. G11C 7/22; G11C 5/14; G11C 8/18

(52) U.S. Cl. CPC G11C 7/22; G11C 8/18; G11C 5/147; G11C 5/148

(57) ABSTRACT

A memory apparatus may include an active control circuit and an internal voltage generation circuit. The active signal generation circuit may enable an internal active signal after a level of a second external power supply voltage is stabilized even when a normal active signal is enabled. The internal voltage generation circuit may generate an internal voltage from a first external power supply voltage based on the internal active signal.

### CROSS-REFERENCES TO RELATED APPLICATION

The present application claims priority under 35 U.S.C. §119(a) to Korean application number 10-2016-0078087 filed on Jun. 22, 2016 in the Korean Intellectual Property Office, which is incorporated herein by reference in its entirety.

### BACKGROUND

### 1. Technical Field

Various embodiments generally relate to a semiconductor technology, and more particularly to an active control circuit, an internal voltage generation circuit, a memory apparatus using the active control circuit, and a system using the active control circuit.

### 2. Related Art

An electronic device consists of a lot of electronic components. A computer system consists of lots of semiconductor devices that use external power sources as their power source. Some semiconductor devices may use two or more external power sources. A non-volatile memory such as a flash memory generally includes a data input/output logic circuit that receives data from an external apparatus or outputs data to the external apparatus. Some semiconductor devices may separately use an external power supply for the data input/output logic circuit and another external power supply for the other internal logic circuits to perform data input/output operations correctly. Some semiconductor devices may also generate internal voltages, which are voltages for internal logic circuits, from external voltages provided by the external power supply.

### SUMMARY

In an embodiment, an active control circuit may include an active delay circuit and an active signal generation circuit. The active delay circuit may generate a delayed active signal based on a control signal after a level of an external power supply voltage is stabilized. The active signal generation circuit may generate an internal active signal based on a normal active signal and the delayed active signal.

In an embodiment, a memory apparatus with an internal voltage generation circuit generating an internal voltage using first and second external power supply voltages may include a stand-by driver, an active driver, and an active control circuit. The stand-by driver may generate an internal voltage from the first external power supply voltage. The active driver may generate the internal voltage from the first external power supply voltage based on an internal active signal. The active control circuit may generate the internal active signal after a level of the second external power supply voltage is stabilized.

In an embodiment, a system may include a plurality of memory apparatuses and a controller. Each of the plurality of memory apparatuses may receive first and second external power supply voltages. The controller may provide a command/address signal to each of the plurality of memory apparatuses. Each of the plurality of memory apparatuses may include an internal voltage generation circuit. The internal voltage generation circuit may include a stand-by driver, an active driver, and an active control circuit. The stand-by driver may generate an internal voltage from the first external power supply voltage. The active driver may generate the internal voltage from the first external power supply voltage based on an internal active signal. The active control circuit may generate the internal active signal based on the command/address signal after a level of the second external power supply voltage is stabilized.

### BRIEF DESCRIPTION OF THE DRAWINGS

Features, aspects and embodiments are described in conjunction with the attached drawings, in which:

FIG. 1 is a diagram illustrating an example configuration of a system in accordance with an embodiment;

FIG. 2 is a diagram illustrating an example of a memory in accordance with an embodiment;

FIG. 3 is a diagram illustrating an example of an active control circuit in accordance with an embodiment;

FIG. 4 is a timing diagram illustrating example operations of the active control circuit of FIG. 3, and a memory apparatus and a system including the active control circuit;

FIG. 5 is a diagram illustrating an example configuration of an active control circuit in accordance with an embodiment;

FIG. 6 is a timing diagram illustrating example operations of the active control circuit of FIG. 5, and a memory apparatus and a system including the active control circuit;

FIG. 7 is a diagram illustrating an example of a data processing system in accordance with an embodiment;

FIG. 8 is a diagram illustrating an example of a solid state drive (SSD) in accordance with an embodiment;

FIG. 9 is a diagram illustrating an example of the SSD controller illustrated in FIG. 8; and

FIG. 10 is a diagram illustrating an example of a computer system containing the data storage device in accordance with an embodiment.

### DETAILED DESCRIPTION

Hereinafter, a semiconductor apparatus according to an embodiment will be described below with reference to the accompanying drawings.

In accordance with an embodiment of the present disclosure, there are provided an active control circuit capable of individually controlling activation timings of memories based on command/address signals provided from a controller, and an internal voltage generation circuit, a memory apparatus and a system using the active control circuit.

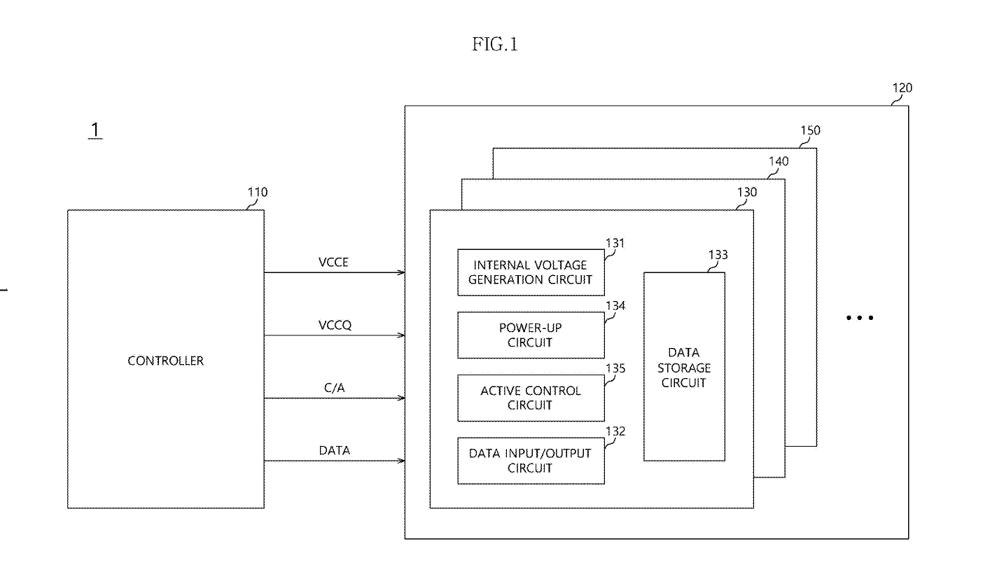

FIG. 1 is a diagram illustrating an example configuration of a system 1 in accordance with an embodiment. Referring to FIG. 1, the system 1 may include a controller 110 and a memory apparatus 120. The controller 110 may exchange data signals with the memory apparatus 120, and may control a data input/output operation of the memory apparatus 120. The memory apparatus 120 may include a plurality of memories. Although FIG. 1 illustrates a memory apparatus 120 having only three memory devices (first to third memories 130, 140, and 150), the number of the memories is not limited thereto. The controller 110 may individually control each of the first to third memories 130, 140, and 150. The memory apparatus 120, which include the first to third memories 130, 140, and 150, may be implemented in a form of a multi-chip package, a ball grid array package, a package on package, a chip on board, a system in package, a wafer-level fabricated package, a wafer-level processed stack package, or combinations thereof. Further, the memory apparatus 120 may serve as a data storage apparatus such as a memory module or a solid state driver.

For example, the controller 110 may be a host apparatus such as a processor, and the processor may include one or more of the central processing unit (CPU), the graphic processing unit (GPU), the multi-media processor (MMP), the digital signal processor. The processor may be implemented in a form of a system on chip (SoC) by combining one or more processor chips having various functions such as application processors (AP). The second semiconductor apparatus 120 may be a memory. The plurality of memories 130, 140, and 150 may include a volatile memory and a non-volatile memory. Examples of the volatile memory may include the static RAM (SRAM), the dynamic RAM (DARM), and the synchronous DRAM (SDRAM). The non-volatile memory may include the read only memory (ROM), the programmable ROM (PROM), the electrically erase and programmable ROM (EEPROM), the electrically programmable ROM (EPROM), the flash memory, the phase change RAM (PRAM), the magnetic RAM (MRAM), the resistive RAM (RRAM), and the ferroelectric RAM (FRAM). Particularly, the plurality of memories 130, 140, and 150 may be operable by one or more external power supply voltages.

The controller 110 may provide the memory apparatus 120 with a command/address signal C/A and data DATA in order to control the operation of the memory apparatus 120. The controller 110 may individually control the each of the first to third memories 130, 140, and 150, and may individually provide the command/address signal C/A to one of the first to third memories 130, 140, and 150 sought to be accessed. Further, the controller 110 may provide the memory apparatus 120 with a first external power supply voltage VCCE and a second external power supply voltage VCCQ. The controller 110 may include a power supply management circuit that receives voltages from a power supply and generates the first and second external power supply voltages VCCE and VCCQ.

Each of the first to third memories 130, 140, and 150 may receive the first and second external power supply voltages VCCE and VCCQ and perform the data input/output operation. Each of the first to third memories 130, 140, and 150 may store the data DATA provided from the controller 110 or may output stored data to the controller 110 in response to the command/address signal C/A provided from the controller 110.

Referring to FIG. 1, the first to third memories 130, 140, and 150 may include the same circuits as one another. The first memory 130, for example, may include an internal voltage generation circuit 131, a data input/output circuit 132, a data storage circuit 133, and a power-up circuit 134. The internal voltage generation circuit 131 may receive the first external power supply voltage VCCE and generate an internal voltage. The internal voltage may be an operating voltage that is used in an internal logic circuit of the first memory 130. The data input/output circuit 132 may receive the data DATA provided from the controller 110, may store the received data DATA into the data storage circuit 133, may read out stored data DATA from the data storage circuit 133, and may output the read out data DATA to the controller 110. To improve the reliability of data transmission, the data input/output circuit 132 may be operable by the second external power supply voltage VCCQ separated from the first external power supply voltage VCCE. That is, the data input/output circuit 132 may have a power domain different from the other internal logic circuits. The data storage circuit 133 may include a memory array that stores data DATA provided from the controller 110, and may include digital circuits and analogue circuits required to store and output the data DATA. The first memory 130 may receive the first external power supply voltage VCCE and generate an internal voltage VCCI before performing the data communication with the controller 110. For example, when a reset signal or a power-on reset signal is enabled, the first memory 130 may be initialized, and then may receive the first external power supply voltage VCCE and generate the internal voltage VCCI. When the internal logic circuits are ready to operate after the first memory 130 receives the first external power supply voltage VCCE, the first memory 130 may receive the second external power supply voltage VCCQ. The power-up circuit 134 may enable a normal active signal when the second external power supply voltage VCCQ is powered up. For example, the power-up circuit 134 may generate the normal active signal when the second external power supply voltage VCCQ rises up to a certain level lower than a target level. The normal active signal may be a signal that instructs the first memory 130 to change its mode from a stand-by mode to an active mode. The normal active signal may also be a signal that instructs the first memory 130 to enter a state in which the first memory 130 receives/outputs data from/to the controller 110.

The first memory 130 may further include an active control circuit 135. The active control circuit 135 may generate an internal active signal. The active control circuit 135 may enable the internal active signal when the level of the second external power supply voltage VCCQ is stabilized. The active control circuit 135 may not enable the internal active signal until the second external power supply voltage VCCQ reaches the target level even if the normal active signal is enabled by the power-up circuit 134. The active control circuit 135 may control the internal voltage generation circuit 131 by generating the internal active signal.

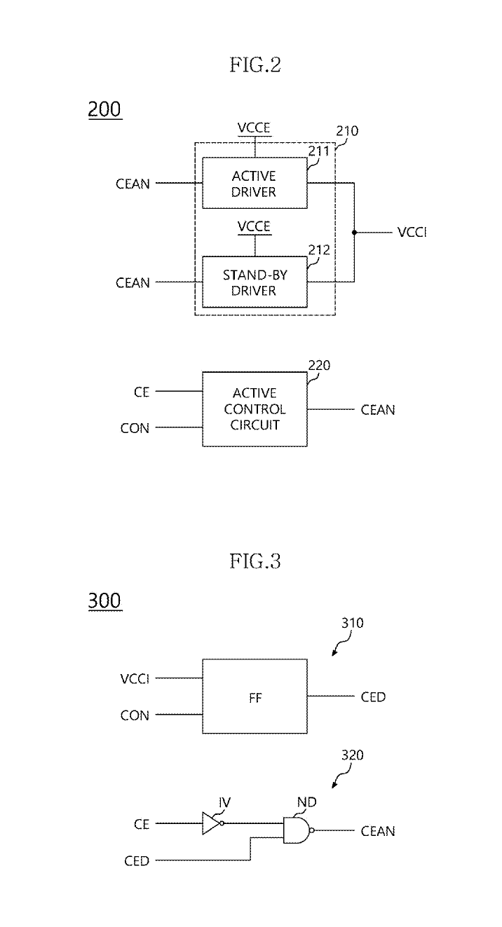

FIG. 2 is a diagram illustrating an example configuration of a memory 200 in accordance with an embodiment. Referring to FIG. 2, the memory 200 may include an internal voltage generation circuit 210 and an active control circuit 220. The memory 200 may be an example of one of the first to third memories 130, 140, and 150, and the internal voltage generation circuit 210 and the active control circuit 220 may be examples of the internal voltage generation circuit 131 and the active control circuit 150, respectively. The internal voltage generation circuit 210 may generate the internal voltage VCCI from the first external power supply voltage VCCE. The active control circuit 220 may include an active driver 211 and a stand-by driver 212. The active driver 211 may generate the internal voltage VCCI from the first external power supply voltage VCCE in an active operation mode of the memory 200. The active driver 211 may be disabled, and may not generate the internal voltage VCCI in a stand-by operation mode of the memory 200. The stand-by driver 212 may generate the internal voltage VCCI from the first external power supply voltage VCCE in the stand-by operation mode of the memory 200. In the active operation mode of the memory 200, the stand-by driver 212 may be disabled, and may not generate the internal voltage VCCI. Alternatively, when the active driver 211 generates the internal voltage VCCI, the stand-by driver 212 may generate the internal voltage VCCI together with the active driver 211. Each of the active driver 211 and the stand-by driver 212 may be implemented with a general voltage generation circuit. The active driver 211 may have greater drivability than the stand-by driver 212, and may consume greater power than the stand-by driver 212. Each of the active driver 211 and the stand-by driver 212 may operate in response to an internal active signal CEAN.

The active control circuit 220 may generate the internal active signal CEAN. The active control circuit 220 may generate the internal active signal CEAN based on a control signal CON and the normal active signal CE. The active control circuit 220 may enable the internal active signal CEAN after the level of the second external power supply voltage VCCQ is stabilized. Whether the second external power supply voltage VCCQ has been stabilized may be determined on the basis of the control signal CON. For example, the control signal CON may be enabled after the level of the second external power supply voltage VCCQ is stabilized. For example, the control signal CON may include a command latch enable signal and a write enable signal. The command latch enable signal and the write enable signal may be generated on the basis of the command/address signal C/A provided from the controller 110. For example, if the memory 200 includes a content addressable memory (CAM), the command latch enable signal may be a signal that is used to read out information stored in the CAM, and the write enable signal may be a signal that is used to perform the write or read operation of the memory apparatus 120. When the controller 110 provides the command/address signal C/A to access the memory 200, the memory 200 may generate the command latch enable signal and the write enable signal based on the command/address signal C/A. In accordance with an embodiment of the present disclosure, the internal active signal CEAN may be generated using the control signal CON, which is generated after enough time has passed for the level of the second external power supply voltage VCCQ to be stabilized. Here, for example, the enough time may be a predetermined period of time. Alternatively, the internal active signal CEAN may be generated by detecting the stabilization of the level of the second external power supply voltage VCCQ in another way.

The active driver 211 may be activated in response to the internal active signal CEAN. The active driver 211 may generate the internal voltage VCCI from the first external power supply voltage VCCE when the internal active signal CEAN is enabled. The stand-by driver 212 may selectively receive the internal active signal CEAN. The stand-by driver 212 may generate the internal voltage VCCI from the first external power supply voltage VCCE when the internal active signal CEAN is disabled. The stand-by driver 212 may be disabled when the internal active signal CEAN is enabled. In an embodiment, the stand-by driver 212 may stay activated, and may generate the internal voltage VCCI along with the active driver 211 even when the internal active signal CEAN is enabled.

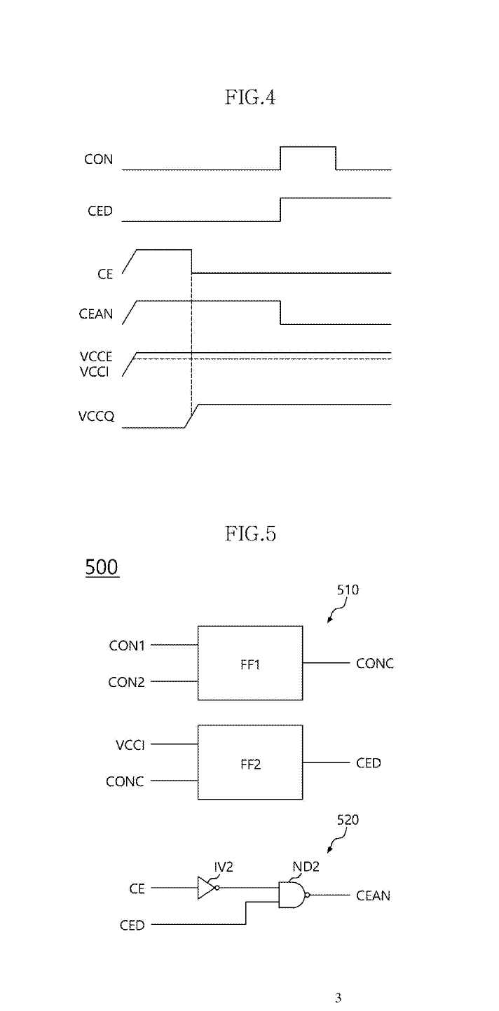

FIG. 3 is a diagram illustrating an example configuration of an active control circuit 300 in accordance with an embodiment. Referring to FIG. 3, the active control circuit 300 may be an example of the active control circuit 150 or 200 of FIGS. 1 and 2. The active control circuit 300 may include an active delay circuit 310 and an active signal generation circuit 320. The active delay circuit 310 may generate a delayed active signal CED based on the control signal CON after the level of the second external power supply voltage VCCQ is stabilized. The active delay circuit 310 may enable the delayed active signal CED when the control signal CON is enabled. The active delay circuit 310 may include a flip-flop FF. The flip-flop FF may receive the internal voltage VCCI and the control signal CON, and may output the delayed active signal CED. The flip-flop FF may enable the delayed active signal CED by outputting the internal voltage VCCI as the delayed active signal CED when the control signal CON is enabled.

The active signal generation circuit 320 may generate the internal active signal CEAN based on the normal active signal CE and the delayed active signal CED. The active signal generation circuit 320 may not enable the internal active signal CEAN until the delayed active signal CED becomes enabled even when the normal active signal CE is enabled. The active signal generation circuit 320 may enable the internal active signal CEAN when both of the normal active signal CE and the delayed active signal CED become enabled. That is, after the normal active signal CE is enabled, the active signal generation circuit 320 may detect that the delayed active signal CED is enabled, and may enable the internal active signal CEAN. The active signal generation circuit 320 may include an inverter IV1 and a NAND gate ND1. The inverter IV1 may invert the normal active signal CE. The NAND gate ND1 may receive an output of the inverter IV1 and the delayed active signal CED, and may output the internal active signal CEAN.

FIG. 4 is a timing diagram illustrating example operations of the active control circuit 300 of FIG. 3. The operations of the memory apparatus 120 and the system 1 in accordance with an embodiment of the present disclosure will be described hereinafter with reference to FIGS. 1 to 4. The internal voltage generation circuit 131 of each of the first to third memories 130, 140, and 150 may generate the internal voltage VCCI when the first external power supply voltage VCCE is supplied. After that, the power-up circuit 134 may generate the normal active signal CE when the second external power supply voltage VCCQ is supplied. If all of the first to third memories 130, 140, and 150 are switched from the stand-by operation mode to the active operation mode based on the normal active signal CE, the active driver 211 of the internal voltage generation circuit 210 may be activated at the same time and generate a peak current, which may lower the level of the first external power supply voltage VCCE. The peak current may cause an incorrect operation of the memory apparatus 120 and the controller 110. In accordance with an embodiment of the present disclosure, even when the normal active signal CE becomes enabled, the active control circuit 300 may enable the internal active signal CEAN only after the control signal CON becomes enabled according to the command/address signal C/A, and thus may prevent the occurrence of the peak current and the lowering of the level of the first external power supply voltage VCCE. It is assumed that the controller 110 accesses the first memory 130 first among the first to third memories 130, 140, and 150. The first memory 130 may receive the command/address signal C/A from the controller 110 while the second and third memories 140 and 150 do not receive the command/address signal C/A. The active control circuit 300 of the first memory 130 may enable the internal active signal CEAN when the control signal CON becomes enabled according to the command/address signal C/A. The internal voltage generation circuit 210 of the first memory 130 may generate the internal voltage VCCI by activating the active driver 211 based on the internal active signal CEAN.

At this time, the second and third memories 140 and 150 do not receive the command/address signal C/A, and thus the active control circuit 300 of the respective second and third memories 140 and 150 may not enable the internal active signal CEAN. After that, when the controller 110 accesses the respective second and third memories 140 and 150, the respective second and third memories 140 and 150 may receive the command/address signal C/A form the controller 110. The active control circuit 300 of the respective second and third memories 140 and 150 may enable the internal active signal CEAN when the control signal CON becomes enabled according to the command/address signal C/A. Therefore, the internal active signal CEAN of the respective first to third memories 130, 140, and 150 may become enabled at different points in time, and thus the active driver 211 of the respective first to third memories 130, 140, and 150 may become activated at different points in time. Accordingly, the active control circuit 300 may prevent the occurrence of the peak current and thus may prevent the lowering of the level of the first external power supply voltage VCCE in the memory apparatus 120.

FIG. 5 is a diagram illustrating an example configuration of an active control circuit 500 in accordance with an embodiment. Referring to FIG. 5, the active control circuit 500 may include an active delay circuit 510 and an active signal generation circuit 520. The active delay circuit 510 may generate a delayed active signal CED based on a first control signal CON1 and a second control signal CON2. The active delay circuit 510 may generate the delayed active signal CED when both of the first and second control signals CON1 and CON2 are enabled. The first and second control signals CON1 and CON2 may be generated on the basis of the command/address signal C/A provided from the controller 110. For example, the first control signal CON1 may include a command latch enable signal, and the second control signal CON2 may be a write enable signal. The active signal generation circuit 520 may generate the internal active signal CEAN based on the normal active signal CE and the delayed active signal CED. The active signal generation circuit 520 may not enable the internal active signal CEAN even when the normal active signal CE is enabled, and may enable the internal active signal CEAN when the delayed active signal CED becomes enabled.

The active delay circuit 510 may include a first flip-flop FF1 and a second flip-flop FF2. The first flip-flop FF1 may receive the first and second control signals CON1 and CON2, and may generate a combined control signal CONC. The first flip-flop FF1 may provide the first control signal CON1 as the combined control signal CONC when the second control signal CON2 is enabled. The first control signal CON1 may be enabled earlier than the second control signal CON2. The second flip-flop FF2 may receive the combined control signal CONC and the internal voltage VCCI, and may generate the delayed active signal CED. The second flip-flop FF2 may output the internal voltage VCCI as the delayed active signal CED when the combined control signal CONC is enabled. The active signal generation circuit 520 may include an inverter IV2 and a NAND gate ND2. The inverter IV2 may delay the normal active signal CE. The NAND gate ND2 may receive the output of the inverter IV1 and the delayed active signal CED, and may output the internal active signal CEAN.

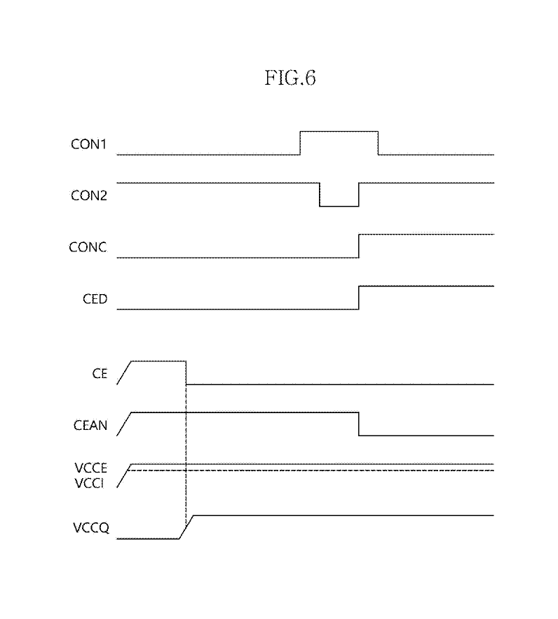

FIG. 6 is a timing diagram illustrating example operations of the active control circuit 500 of FIG. 5. The operations of the memory apparatus 120 and the system 1 in accordance with an embodiment of the present disclosure will be described hereinafter with reference to FIGS. 1, 2, 5, and 6. Each of the first to third memories 130, 140, and 150 may receive the first external power supply voltage VCCE, and may generate the internal voltage VCCI. After that, the power-up circuit 134 may enable the normal active signal CE (e.g., a low level) when the second external power supply voltage VCCQ is applied. The active control circuit 500 may not enable the internal active signal CEAN even when the normal active signal CE becomes enabled. When the controller 110 accesses the first memory 130 first among the first to third memories 130, 140, and 150, the first memory 130 may receive the command/address signal C/A from the controller 110, and may generate the first and second control signals CON1 and CON2. At this time, the respective second and third memories 140 and 150 may not receive the command/address signal C/A, and thus may not generate the first and second control signals CON1 and CON2.

When the first control signal CON1 becomes enabled (e.g., a high level) and the second control signal CON2 becomes enabled (e.g., a low level), the active delay circuit 510 of the first memory 130 may enable the combined control signal CONC (e.g., a high level). When the combined control signal CONC becomes enabled, the delayed active signal CED may be enabled (e.g., a high level). When the delayed active signal CED becomes enabled, the active signal generation circuit 520 of the first memory 130 may enable the internal active signal CEAN (e.g., a low level). When the internal active signal CEAN becomes enabled, the active driver 211 in the internal voltage generation circuit 210 of the first memory 130 may be activated, and may generate the internal voltage VCCI from the first external power supply voltage VCCE. At this time, the respective second and third memories 140 and 150 may not generate the internal active signal CEAN until the respective second and third memories 140 and 150 receive the command/address signal C/A from the controller 110, and thus the occurrence of the peak current may be suppressed in the memory apparatus 120.

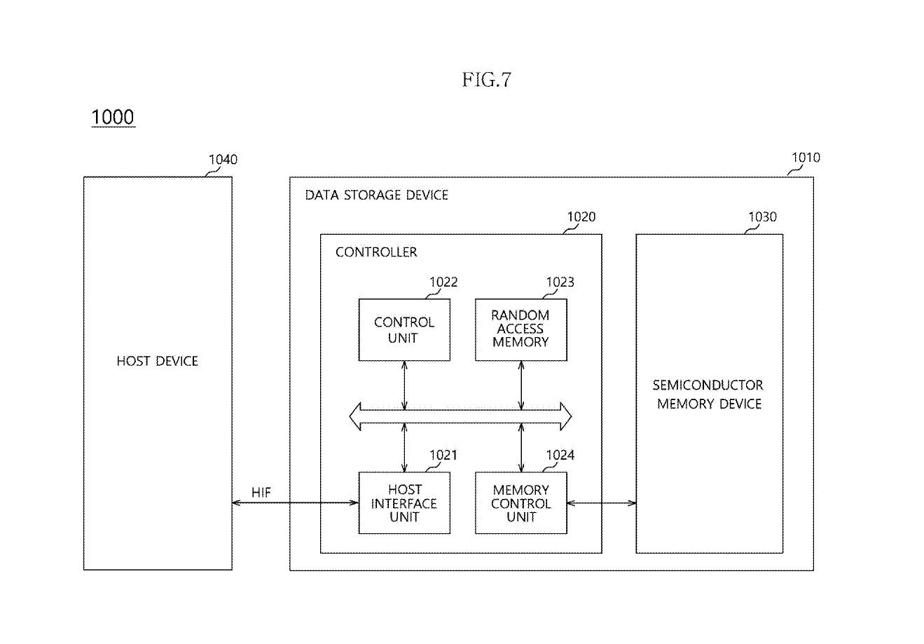

FIG. 7 is a diagram illustrating of an example of a data processing system in accordance with an embodiment. A data processing system 1000 may include a host device 1040. Examples of the host device 1040 may include portable electronic devices such as a mobile phone, an MP3 player and a laptop computer, and may include electronic devices such as a desktop computer, a game player, a TV and an in-vehicle infotainment system.

The data processing system 1000 may include a data storage device 1010. The data storage device 1010 may store data that will be read by the host device 1040. The data storage device 1010 may also be referred to as a memory system.

The data storage device 1010 may be implemented according to a host interface HIF meaning a transmission protocol with respect to the host device 1040. Examples of the data storage device 1010 may include a solid state drive (SSD), a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a personal computer memory card international association (PCMCIA) card type storage device, a peripheral component interconnection (PCI) card type storage device, a PCI express (PCI-E) card type storage device, a compact flash (CF) card, a smart media card, a memory stick, and so forth.

The data storage device 1010 may be manufactured as one of various kinds of packages. Examples of the data storage device 1010 may include a package-on-package (POP), a system-in-package (SIP), a system-on-chip (SOC), a multi-chip package (MCP), a chip-on-board (COB), a wafer-level fabricated package (WFP), and a wafer-level stack package (WSP).

The data storage device 1010 may include a controller 1020. The controller 1020 may include a host interface unit 1021, a control unit 1022, a random access memory 1023, and a memory control unit 1024.

The host interface unit 1021 may interface the host device 1040 and the data storage device 1010. For example, the host interface unit 1021 may communicate with the host device 1040 by using a standard transmission protocol such as universal serial bus (USB), universal flash storage (UFS), multimedia card (MMC), parallel advanced technology attachment (PATA), serial advanced technology attachment (SATA), small computer system interface (SCSI), serial attached SCSI (SAS), peripheral component interconnection (PCI), and PCI express (PCI-E) protocols.

The control unit 1022 may control general operations of the controller 1020. The control unit 1022 may execute an instruction or an algorithm (e.g., software) loaded in the random access memory 1023, and may control operations of functional blocks in the controller 1020. The control unit 1022 may analyze and process a request of the host device 1040 transmitted through the host interface unit 1021. The control unit 1022 may include a micro control unit (MCU) or a central processing unit (CPU).

The random access memory 1023 may store a software program that will be executed by the control unit 1022. The random access memory 1023 may store data necessary for the execution of the software. That is to say, the random access memory 1023 may operate as a working memory of the control unit 1022.

The random access memory 1023 may temporarily store data that will be transmitted from the host device 1040 to a semiconductor memory device 1030 or from the semiconductor memory device 1030 to the host device 1040. In other words, the random access memory 1023 may operate as a data buffer memory or a data cache memory.

The memory control unit 1024 may control the semiconductor memory device 1030 according to control signals of the control unit 1022. The memory control unit 1024 may generate signals for controlling the operation of the semiconductor memory device 1030, for example, commands, addresses, clock signals and so forth, and may provide the generated signals to the semiconductor memory device 1030. The memory control unit 1024 may also be referred to as a memory interface unit.

The data storage device 1010 may include the semiconductor memory device 1030. The semiconductor memory device 1030 may be used as the storage medium of the data storage device 1010. The semiconductor memory device 1030 may be a nonvolatile memory device such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase change random access memory (PCRAM) using a chalcogenide alloy, and a resistive random access memory (RERAM) using a transition metal oxide. The ferroelectric random access memory (FRAM), the magnetic random access memory (MRAM), the phase change random access memory (PCRAM) and the resistive random access memory (RERAM) may be implemented in a form of nonvolatile random access memory device. The semiconductor memory device 1030 may be a combination of a NAND flash memory device and one or more of the above-described various types of nonvolatile random access memory devices. The controller 110 of FIG. 1 may be provided as the controller 1040, and the memory device 120 of FIG. 1 may be provided as the semiconductor memory device 1030.

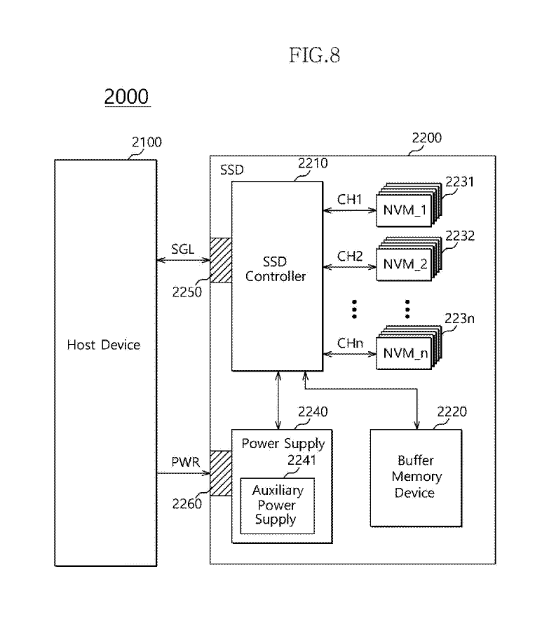

FIG. 8 is a diagram illustrating an example of a solid state drive (SSD) in accordance with an embodiment. Referring to FIG. 8, a data processing system 2000 may include a host device 2100 and a solid state drive (SSD) 2200.

The SSD 2200 may include an SSD controller 2210, a buffer memory device 2220, nonvolatile memory devices 2231 to 223n, a power supply 2240, a signal connector 2250, and a power connector 2260.

The SSD 2200 may operate in response to a request of the host device 2100. In other words, the SSD controller 2210 may access the nonvolatile memory devices 2231 to 223n in response to a request from the host device 2100. For example, the SSD controller 2210 may control read, program and erase operations of the nonvolatile memory devices 2231 to 223n.

The buffer memory device 2220 may temporarily store data that will be written in the nonvolatile memory devices 2231 to 223n. Further, the buffer memory device 2220 may temporarily store data read out from the nonvolatile memory devices 2231 to 223n. The data temporarily stored in the buffer memory device 2220 may be transmitted to the host device 2100 or the nonvolatile memory devices 2231 to 223n under control of the SSD controller 2210.

The nonvolatile memory devices 2231 to 223n may be used as storage media of the SSD 2200. The nonvolatile memory devices 2231 to 223n may be coupled to the SSD controller 2210 through a plurality of channels CH1 to CHn, respectively. One or more nonvolatile memory devices may be coupled to one channel. The nonvolatile memory devices coupled to the same channel may be coupled to the same signal bus and data bus.

The power supply 2240 may provide, to the inside of the SSD 2200, power PWR input through the power connector 2260. The power supply 2240 may include an auxiliary power supply 2241. The auxiliary power supply 2241 may supply power to allow operations of the SSD 2200 to be normally terminated when a sudden power-off occurs. The auxiliary power supply 2241 may include large-capacitance capacitors capable of storing power PWR.

The SSD controller 2210 may exchange a signal SGL with the host device 2100 through the signal connector 2250. The signal SGL may include a command, an address, data, and so forth. Examples of the signal connector 2250 may include parallel advanced technology attachment (PATA), serial advanced technology attachment (SATA), small computer system interface (SCSI), serial attached SCSI (SAS), peripheral component interconnection (PCI), PCI express (PCI-E) and universal flash storage (UFS) protocols, according to an interface scheme between the host device 2100 and the SSD 2200. For example, the controller 110 of FIG. 1 may correspond to the SSD controller 2210 and the power supply 2240, and the memory device 120 of FIG. 1 may correspond to the respective nonvolatile memory devices 2231 to 223n.

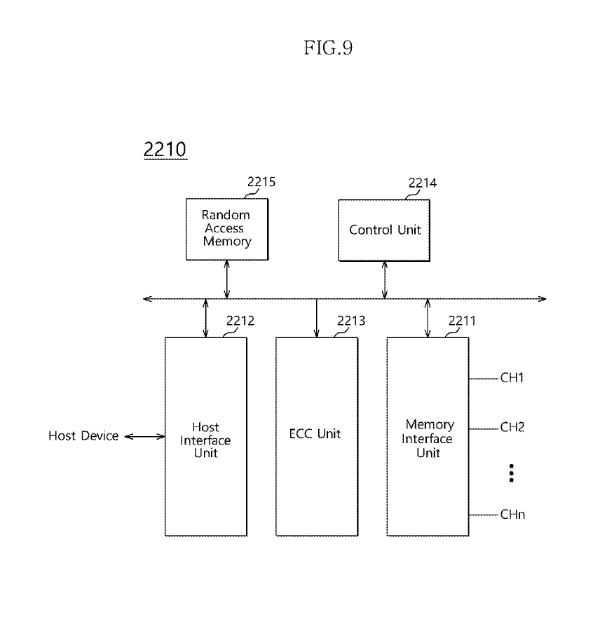

FIG. 9 is a diagram illustrating an example of the SSD controller illustrated in FIG. 8. Referring to FIG. 9, the SSD controller 2210 may include a memory interface unit 2211, a host interface unit 2212, an error correction code (ECC) unit 2213, a control unit 2214, and a random access memory 2215.

The memory interface unit 2211 may provide commands and addresses to the nonvolatile memory devices 2231 to 223n. Moreover, the memory interface unit 2211 may exchange data with the nonvolatile memory devices 2231 to 223n. The memory interface unit 2211 may scatter data transmitted from the buffer memory device 2220 to the respective channels CH1 to CHn, under control of the control unit 2214. Furthermore, the memory interface unit 2211 may transmit data read out from the nonvolatile memory devices 2231 to 223n to the buffer memory device 2220, under control of the control unit 2214.

The host interface unit 2212 may provide an interface with respect to the SSD 2200 in compliance with the protocol of the host device 2100. For example, the host interface unit 2212 may communicate with the host device 2100 through a protocol such as parallel advanced technology attachment (PATA), serial advanced technology attachment (SATA), small computer system interface (SCSI), serial attached SCSI (SAS), peripheral component interconnection (PCI), PCI express (PCI-E), and universal flash storage (UFS) protocols. In addition, the host interface unit 2212 may perform a disk emulating function of supporting the host device 2100 to recognize the SSD 2200 as a hard disk drive (HDD).

The error correction code (ECC) unit 2213 may generate parity data to be transmitted to the nonvolatile memory devices 2231 to 223n, among data stored in the buffer memory device 2220. The generated parity data may be stored, along with data, in the nonvolatile memory devices 2231 to 223n. The error correction code (ECC) unit 2213 may detect an error in the data read out from the nonvolatile memory devices 2231 to 223n. When the detected error is within a correctable range, the error correction code (ECC) unit 2213 may correct the detected error.

The control unit 2214 may analyze and process the signal SGL input from the host device 2100. The control unit 2214 may control operations of the buffer memory device 2220 and the nonvolatile memory devices 2231 to 223n according to firmware or software for driving the SSD 2200. The random access memory 2215 may be used as a working memory for driving the firmware or the software.

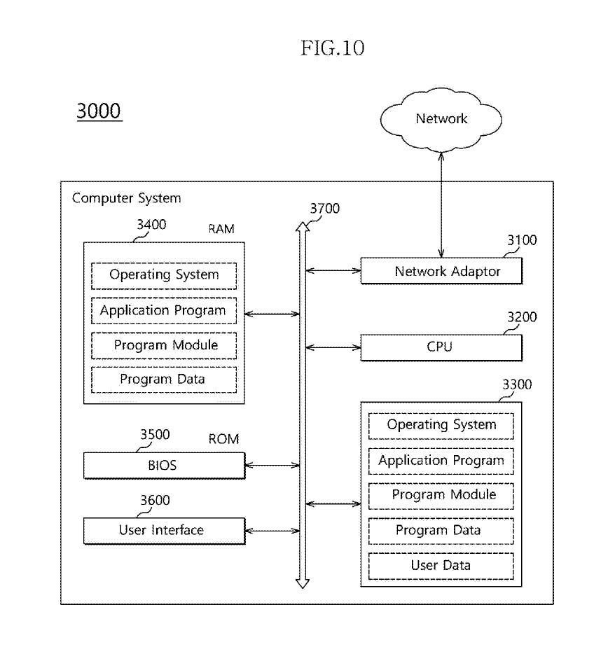

FIG. 10 is a diagram illustrating an example of a computer system containing the data storage device in accordance with an embodiment. Referring to FIG. 10, a computer system 3000 may include a network adaptor 3100, a central processing unit 3200, a data storage device 3300, a RAM 3400, a ROM 3500 and a user interface 3600, which are electrically coupled to a system bus 3700. The data storage device 3300 may be composed of the data storage device 1010 illustrated in FIG. 7 or the SSD 2200 illustrated in FIG. 8.

The network adaptor 3100 may provide an interface between the computer system 3000 and external networks. The central processing unit 3200 may perform general calculation operations for driving an operating system residing at the RAM 3400 or an application program.

The data storage device 3300 may store general data needed in the computer system 3000. For example, an operating system for driving the computer system 3000, an application program, various program modules, program data and user data may be stored in the data storage device 3300.

The RAM 3400 may be used as the working memory of the computer system 3000. Upon booting, the operating system, the application program, the various program modules and the program data needed for driving programs, which are read out from the data storage device 3300, may be loaded in the RAM 3400. A basic input/output system (BIOS) activated before the operating system is driven may be stored in the ROM 3500. Information exchange between the computer system 3000 and a user may be implemented through the user interface 3600.

While certain embodiments have been described above, it will be understood to those skilled in the art that the embodiments described are by way of example only. Accordingly, the active control circuit, internal voltage generation circuit, memory apparatus and system using the same should not be limited based on the described embodiments. Rather, the active control circuit, internal voltage generation circuit, memory apparatus and system using the same described herein should only be limited in light of the claims that follow when taken in conjunction with the above description and accompanying drawings.

1-6. (canceled)

7. A memory apparatus with an internal voltage generation circuit generating an internal voltage using first and second external power supply voltages, comprising:
a stand-by driver configured to generate an internal voltage from the first external power supply voltage;
an active driver configured to generate the internal voltage from the first external power supply voltage based on an internal active signal; and
an active control circuit configured to generate the internal active signal after a level of the second external power supply voltage which is separated from the first external power supply voltage is stabilized.

8. The memory apparatus of claim 7, wherein the stand-by driver is disabled in response to the internal active signal.

9. The memory apparatus of claim 7, wherein the active control circuit includes:
an active delay circuit configured to generate a delayed active signal based on a control signal after the level of the second external power voltage is stabilized; and
an active signal generation circuit configured to generate the internal active signal based on a normal active signal and the delayed active signal.

10. The active control circuit of claim 9, wherein the control signal becomes enabled after a predetermined time has passed for the level of the external power supply voltage to be stabilized.

11. The memory apparatus of claim 9, wherein the control signal is generated on the basis of a command/address signal provided from a controller.

12. The memory apparatus of claim 9, wherein the active delay circuit includes a flip-flop configured to generate the delayed active signal when the control signal is enabled in response to a command/address signal.

13. The memory apparatus of claim 9, wherein the control signal includes first and second control signals, and
wherein the active delay circuit includes:
a first flip-flop configured to generate a combined control signal when the first and second control signals become enabled; and
a second flip-flop configured to generate the delayed active signal when the combined control signal becomes enabled.

14. The memory apparatus of claim 9, wherein the active signal generation circuit prevents the internal active signal from being enabled even when the normal active signal is enabled, and enables the internal active signal when the delayed active signal becomes enabled.

15. A system comprising:
a plurality of memory apparatuses each configured to receive a first external power supply voltage and a second external power supply voltage which is separated from the first external power supply voltage;
a controller configured to provide a command/address signal to each of the plurality of memory apparatuses,
wherein each of the plurality of memory apparatuses has an internal voltage generation circuit including:
a stand-by driver configured to generate an internal voltage from the first external power supply voltage;
an active driver configured to generate the internal voltage from the first external power supply voltage based on an internal active signal; and
an active control circuit configured to generate the internal active signal based on the command/address signal after a level of the second external power supply voltage is stabilized.

16. The system of claim 15, wherein the stand-by driver is disabled in response to the internal active signal.

17. The system of claim 15, wherein the active control circuit includes:
an active delay circuit configured to generate a delayed active signal based on a control signal generated according to the command/address signal after the level of the second external power voltage is stabilized; and
an active signal generation circuit configured to generate the internal active signal based on an external active signal and the delayed active signal.

18. The system of claim 17, wherein the active delay circuit includes a flip-flop configured to generate the delayed active signal when the control signal is enabled.

19. The system of claim 17, wherein the control signal includes first and second control signals, and
wherein the active delay circuit includes:
a first flip-flop configured to generate a combined control signal when the first and second control signals become enabled; and
a second flip-flop configured to generate the delayed active signal when the combined control signal becomes enabled.

20. The system of claim 17, wherein the active signal generation circuit prevents the internal active signal from being enabled even when the external active signal is enabled, and enables the internal active signal when the delayed active signal becomes enabled.
